(19) United States
(12) Patent Application Publication
(10) Pub. No.: US 2012/0305299 A1
(43) Pub. Date: Dec. 6, 2012

(54) PRINTED CIRCUIT BOARD WITH REFERENCE LAYER HOLE

(75) Inventors: CHUN-SHENG CHEN, Tu-Cheng (TW); HUA ZOU, Shenzhen City (CN); FENG-LONG HE, Shenzhen City (CN)

(73) Assignee: HON HAI PRECISION INDUSTRY CO., LTD., Tu-Cheng, New Taipei (TW)

(21) Appl. No.: 13/275,330

(22) Filed: Oct. 18, 2011

(30) Foreign Application Priority Data
Jun. 3, 2011 (CN) 201110148535.X

(51) Int. Cl. H05K 1/09; H05K 1/11

(52) U.S. Cl. 174/257; 174/266

(57) ABSTRACT

An exemplary PCB defines a circular first via and includes a first signal layer, a second signal layer, a first reference layer between the first and second signal layer, and a signal transmission line having a first portion on the first signal layer and a second portion on the second signal layer. The first signal layer has a circular first weld pad coaxial with the first via and electrically connected to the first portion, the second layer has a circular second weld pad coaxial with the first via and electrically connected to the second portion. The first weld pad is electrically connected to the second weld pad through the first via, the reference layer defines a first through hole coaxial with the first via, the radius of the first via is R1, the radius of the first through hole is R2, R2=R1+d1, 1.5 mil≦d1≦4 mil.

### BACKGROUND

1. Technical Field

The present disclosure relates to a printed circuit board (PCB) configured for reducing signal loss of signal transmission lines.

2. Description of Related Art

PCBs usually have a number of signal transmission lines arranged therein. Each signal transmission line may be arranged on two signal layers of the PCB. The two parts of the signal transmission line on the two signal layers are electrically connected to each other through a via that passes between the two signal layers. Each of the two signal layers has a weld pad arranged therein, wherein the weld pad is coaxial with the via. Each of the two signal layers functions in cooperation with an adjacent (nearest) reference layer, which is typically a piece of grounded copper foil. Thus a parallel plate condenser is generated between each weld pad and the adjacent reference layer, and parasitic capacitance of the parallel plate condenser increases signal loss of the corresponding signal transmission line.

Therefore, it is desirable to provide a PCB that can overcome the above-mentioned limitations.

### BRIEF DESCRIPTION OF THE DRAWINGS

Many aspects of the embodiments should be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic top view of part of a PCB, according to a first exemplary embodiment.

FIG. 2 is a sectional view of the PCB of FIG. 1, taken along a line II-II thereof.

FIG. 3 is a sectional view of part of a PCB, according to a second exemplary embodiment.

### DETAILED DESCRIPTION

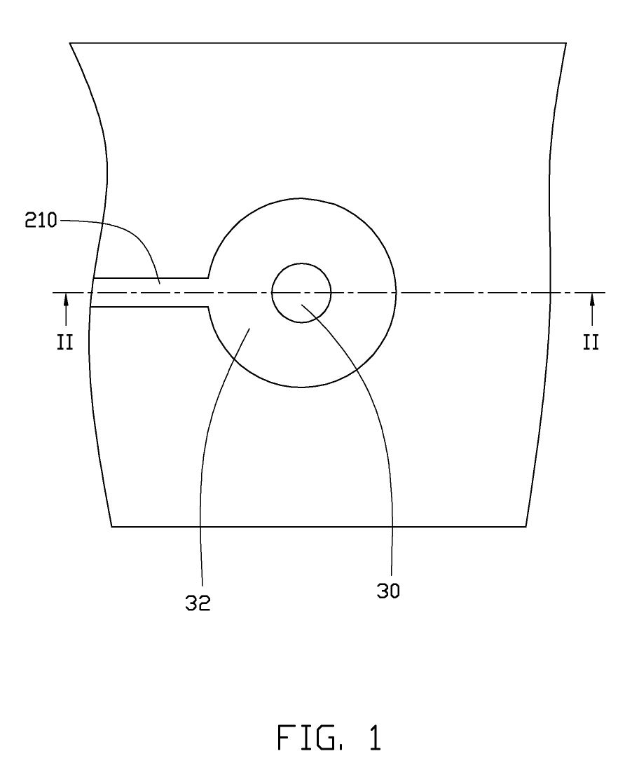

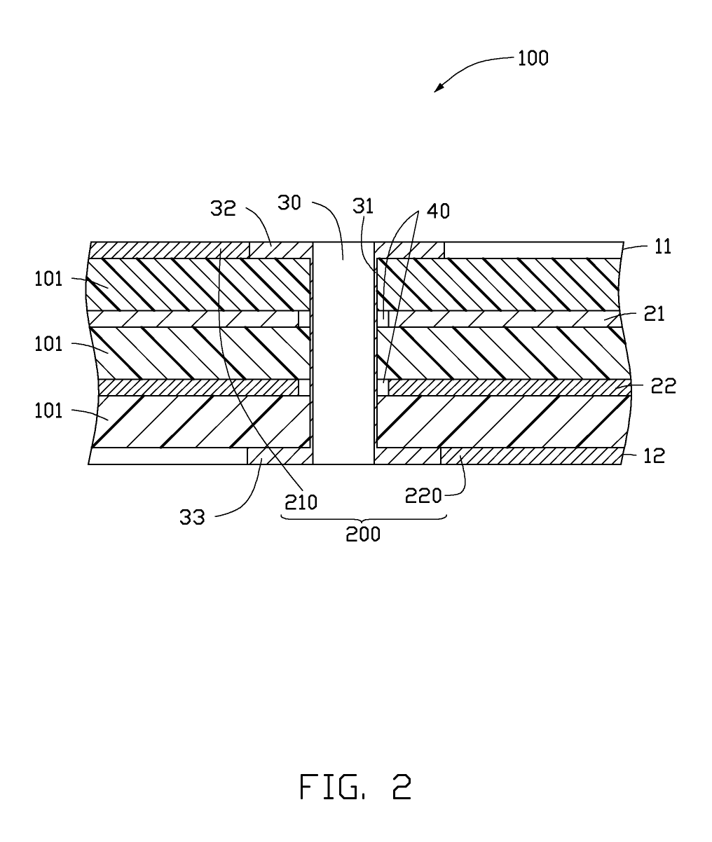

Referring to FIG. 1 and FIG. 2, a PCB 100, according to a first exemplary embodiment, includes four circuit layers 11, 12, 21, 22 and three insulation layers 101. The circuit layers 11, 12, 21, 22 and the insulation layers 101 are stacked alternately, with one insulation layer 101 laid between every two adjacent circuit layers 11, 12, 21, 22. The four circuit layers are a first signal layer 11, a second signal layer 12, a first reference layer 21, and a second reference layer 22. The first reference layer 21 and the second reference layer 22 are arranged between the first signal layer 11 and the second signal layer 12. The first reference layer 21 is adjacent to (nearest) the first signal layer 11, and the second reference layer 22 is adjacent to (nearest) the second signal layer 12. Thus the first signal layer 11 functions in cooperation with the first reference layer 21, and the second signal layer 12 functions in cooperation with the second reference layer 22. The PCB 100 may be equipped in a universal serial bus (USB) 3.0 device. In general, the number of reference layers is not limited to the two reference layers 21, 22 of this embodiment.

A signal transmission line 200 is arranged on the PCB 100, and includes a first portion 210 and a second portion 220. The first portion 210 is arranged on the first signal layer 11. The second portion 220 is arranged on the second signal layer 12.

The PCB 100 defines a via 30 passing through the first signal layer 11, the first reference layer 21, the second reference layer 22, the second signal layer 12, and the insulation layers 101. The first signal layer 11 has a circular first weld pad 32 arranged therein, wherein the first weld pad 32 is coaxial with the via 30. The second signal layer 12 has a circular second weld pad 33 arranged therein, wherein the second weld pad 33 is coaxial with the via 30. The first portion 210 is electrically connected to the first weld pad 32. The second portion 220 is electrically connected to the second weld pad 33. The inner sidewall of the via 30 is coated with a conductive film 31 electrically connected to the first weld pad 32 and the second weld pad 33. Thus the first portion 210 is electrically connected to the second portion 220.

Each of the first reference layer 21 and the second reference layer 22 is a piece of grounding copper foil, and defines a circular through hole 40 coaxial with the via 30. The radius of the through hole 40 is substantially larger than that of the via 30. The radius of the via 30 is R1, the radius of the through hole 40 is R2, and the difference between the radius of the through hole 40 and the radius of the via 30 is a predetermined value d1; that is, R2=R1+d1. Typically, 1.5 mils≦d1≦4 mils (1 mil=0.0254 mm) In this embodiment, d1=3 mils.

Table 1 shows the relationship between the values of d1 and the signal loss of the signal transmission line 200 when the frequency of signals in the signal transmission line 200 is 5 gigahertz (GHz).

TABLE 1

| | d1 (mil) | | | | |
|---|---|---|---|---|---|
| | −3 | 0 | 1.5 | 2.5 | 3 |
| Signal loss (decibel, dB) | −1.47 | −1.20 | −1.10 | −1.07 | −1.06 |

d1 (mil)

| | 4 | 5 | 6 | 6.5 |
|---|---|---|---|---|
| Signal loss (dB) | −1.06 | −1.12 | −1.13 | −1.21 |

Referring to table 1, when 1.5 mils≦d1≦4 mils, the signal loss of the signal transmission line 200 is less. In particular, when d1=3 mils or 4 mils, the signal loss of the signal transmission line 200 is least.

Because the first reference layer 21 is not electrically connected to the weld pad 32, the first reference layer 21 and the weld pad 32 cooperatively form a parallel plate condenser therebetween. Additionally, the second reference layer 22 is not electrically connected to the weld pad 33, thus the second reference layer 22 and the weld pad 33 cooperatively form a parallel plate condenser therebetween. According to the formula

$$C = \frac{K ξ S}{D} ,$$

is the capacitance of a parallel plate condenser, K is a constant, ζ is a dielectric constant of material between the two polar plates, S is the area of the facing surfaces of the two polar plates (i.e. the first reference layer 21 and the weld pad 32, or the second reference layer 22 and the weld pad 33) of the parallel plate condenser, and D is the distance between the two polar plates. Because each of the first reference layer 21 and the second reference layer 22 defines a circular through hole 40 coaxial with the via 30, the value of S is reduced, and so the value of C is also reduced. Therefore the parasitic capacitance of the PCB 100 is reduced, and accordingly the signal loss of the signal transmission line 200 is reduced. However, many experiments show that if d1 is too large (i.e. d1>4 mils), or d1 is too small (i.e. d1<1.5 mils), the signal loss of the signal transmission line 200 becomes larger than that of the signal transmission line 200 when 1.5 mils≦d1≦4 mils.

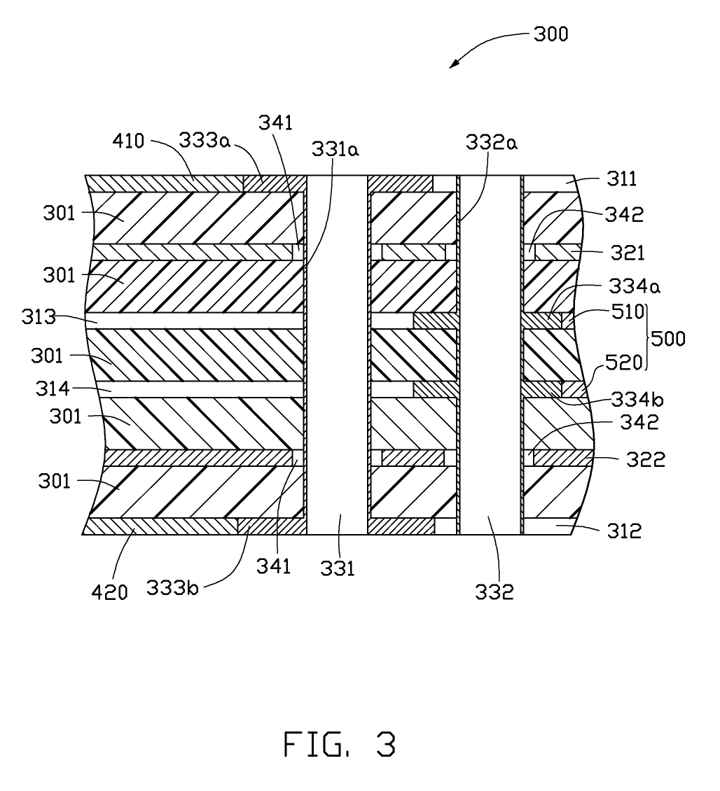

Referring to FIG. 3, a PCB 300, according to a second exemplary embodiment, includes six circuit layers and five insulation layers 301. The PCB 300 defines a first via 331 and a second via 332 passing through the six circuit layers and the five insulation layers 301. The six circuit layers include, from top to bottom, a first signal layer 311, a first reference layer 321, a third signal layer 313, a fourth signal layer 314, a second reference layer 322, and a second signal layer 312.

Both of the first signal layer 311 and the third signal layer 313 function in cooperation with the first reference layer 321. Both of the second signal layer 312 and the fourth signal layer 314 function in cooperation with the second reference layer 322. A first signal transmission line (not marked) and a second signal transmission line 500 are arranged on the PCB 300. The first signal layer 311 has a first weld pad 333a arranged therein, and the second signal layer 312 has a second weld pad 333b arranged therein. The first weld pad 333a and the second weld pad 333b are coaxial with a first via 331. The third signal layer 313 has a third weld pad 334a arranged therein, and the fourth signal layer 314 has a fourth weld pad 334b arranged therein. The third weld pad 334a and the fourth weld pad 334b are coaxial with a second via 332.

The first signal transmission line includes a first portion 410 and a second portion 420. The first portion 410 is arranged on the first signal layer 311 and electrically connected to the first weld pad 333a. The second portion 420 is arranged on the second signal layer 312 and electrically connected to the second weld pad 333b. The second signal transmission line 500 includes a third portion 510 and a fourth portion 520. The third portion 510 is arranged on the third signal layer 313 and electrically connected to the third weld pad 334a. The fourth portion 520 is arranged on the fourth signal layer 314 and electrically connected to the fourth weld pad 334b. The first weld pads 333a and the second weld pad 333b are electrically connected to a conductive film 331a coated on the inner sidewall of the first via 331, and thus the first portion 410 is electrically connected to the second portion 420. The third weld pad 334a and the fourth weld pad 334b are electrically connected to a conductive film 332a coated on the inner sidewall of the second via 332, and thus the third portion 510 is electrically connected to the fourth portion 520.

Each of the first reference layer 321 and the second reference layer 322 is a piece of grounding copper foil, and defines a circular first through hole 341 coaxial with the first via 331, and a circular second through hole 342 coaxial with the second via 332.

The radius of the first via 331 is R1, the radius of each first through hole 341 is R2, the radius of the second via 332 is R3, and the radius of each second through hole 342 is R4, wherein R2=R1+d1, R4=R3+d2, 1.5 mils≦d1≦4 mils, and 1.5 mils≦d2≦4 mils.

In other embodiments, the first portion 410 may be arranged on both the first signal layer 311 and the third signal layer 313, and the second portion 420 may be arranged on both the second signal layer 312 and the fourth signal layer 314. In such case, the two first portions 410 and the two second portions 420 are electrically connected to the conductive film 331a coated on the inner sidewall of the first via 331. The third portion 510 may be arranged on both the first signal layer 311 and the third signal layer 313, and the fourth portion 520 may be arranged on both the second signal layer 312 and the fourth signal layer 314. In such case, the two third portions 510 and the two fourth portions 520 are electrically connected to the conductive film 332a coated on the inner sidewall of the second via 332.

In this embodiment, the second via 332 passes through all the circuit layers and all the insulation layers 301 to simplify the process of manufacturing the PCB 300. In other embodiments, the second via 332 may only pass through the third signal layer 313, the fourth signal layer 314, and the insulation layer 301 therebetween.

In other embodiments, the PCB may include eight layers, ten layers or more than ten layers. When the first portion and the second portion of a given signal transmission line are arranged on two or more signal layers, and electrically connected to each other through the corresponding via, then each of the two or more reference layers respectively corresponding to the two or more signal layers may have a through hole defined therein corresponding to the via.

In other embodiments, the number of signal transmission lines is not limited to the one signal transmission line 200 or the two signal transmission lines of the above-described first and second exemplary embodiments.

It will be further understood that the above particular embodiments and methods are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. A printed circuit board (PCB) comprising:
at least three circuit layers comprising:
a first signal layer,
a second signal layer, and
at least one first reference layer arranged between the first signal layer and the second signal layer, and
at least two insulation layers, wherein each insulation layer is arranged between two corresponding adjacent circuit layers; and
at least one signal transmission line, each signal transmission line comprising:
a first portion arranged on the first signal layer, and
a second portion arranged on the second signal layer;
wherein the PCB defines at least one circular first via passing through the at least three circuit layers, and the at least two insulation layers, the first signal layer has a circular first weld pad arranged therein, the first weld pad is coaxial with the first via and electrically connected to the first portion, the second signal layer has a circular second weld pad arranged therein, the second weld pad is coaxial with the first via and electrically connected to the second portion, an inner sidewall of the first via is coated with a conductive film electrically connected with the first weld pad and the second weld pad, the at least one reference layer defines a first through hole coaxial with the first via, the radius of the first via is R1, and the radius of the first through hole is R2, and wherein R2=R1+d1, with 1.5 mil≦d1≦4 mil.

2. The PCB of claim 1, wherein the value of d1 is approximately 3 mils or approximately 4 mils.

3. The PCB of claim 1, wherein the at least one reference layer comprises a first reference layer and a second reference layer, the first reference layer is adjacent to the first signal layer, and the second reference layer is adjacent to the second signal layer, and thus the first signal layer functions in cooperation with the first reference layer, and the second signal layer functions in cooperation with the second reference layer.

4. The PCB of claim 3, wherein each of the first reference layer and the second reference layer is a piece of grounding copper foil.

5. The PCB of claim 3, wherein the at least three circuit layers further comprise a third signal layer and a fourth signal layer both arranged between the first reference layer and the second reference layer, the third signal layer is adjacent to the first reference layer, the fourth signal layer is adjacent to the second reference layer, and one of the at least two insulation layers is arranged between the third signal layer and the fourth signal layer.

6. The PCB of claim 5, wherein the PCB defines at least one circular second via passing the at least three circuit layers, the third signal layer has a third weld pad arranged therein, the fourth signal layer has a fourth weld pad arranged therein, the third weld pad and the fourth weld pad are coaxial with the second via and electrically connected to the conductive film coated on the inner sidewall of the second via, the PCB further has at least one second signal transmission line, each second transmission line comprises a third portion and the fourth portion, the third portion is arranged in the third signal layer corresponding to the third weld pad, the fourth portion is arranged in the fourth signal layer corresponding to the fourth weld pad, each of the first reference layer and the second reference layer defines a second through hole coaxial with the second via, the radius of the second via is R3, and the radius of the second through hole is R4, and wherein R4=R3+d2, with 1.5 mils≦d2≦4 mils.

7. The PCB of claim 6, wherein the value of d2 is approximately 3 mils or approximately 4 mils.

8. The PCB of claim 6, wherein the second via further passes through the at least two insulation layers.

9. A printed circuit board (PCB) comprising:
at least three circuit layers comprising:
a first signal layer,
a second signal layer, and
at least one first reference layer arranged between the first signal layer and the second signal layer, and
at least one signal transmission line, each signal transmission line comprising:
a first portion arranged on the first signal layer, and
a second portion arranged on the second signal layer;
wherein the PCB defines at least one circular first via passing through the at least three circuit layers, the first signal layer has a circular first weld pad arranged therein, the first weld pad is coaxial with the first via and electrically connected to the first portion, the second signal layer has a circular second weld pad arranged therein, the second weld pad is coaxial with the first via and electrically connected to the second portion, an inner sidewall of the first via is coated with a conductive film electrically connected with the first weld pad and the second weld pad, the at least one reference layer defines a first through hole coaxial with the first via, the radius of the first via is R1, and the radius of the first through hole is R2, and wherein R2=R1+d1, with 1.5 mil≦d1≦4 mil.

10. The PCB of claim 9, wherein the value of d1 is approximately 3 mils or approximately 4 mils.

11. The PCB of claim 9, wherein the at least one reference layer comprises a first reference layer and a second reference layer, the first reference layer is adjacent to the first signal layer, and the second reference layer is adjacent to the second signal layer, and thus the first signal layer functions in cooperation with the first reference layer, and the second signal layer functions in cooperation with the second reference layer.

12. The PCB of claim 11, wherein each of the first reference layer and the second reference layer is a piece of grounding copper foil.

13. The PCB of claim 11, wherein the at least three circuit layers further comprise a third signal layer and a fourth signal layer both arranged between the first reference layer and the second reference layer, the third signal layer is adjacent to the first reference layer, the fourth signal layer is adjacent to the second reference layer, an insulation layer is arranged between the third signal layer and the fourth signal layer.

14. The PCB of claim 11, wherein the PCB defines at least one circular second via passing the at least three circuit layers, the third signal layer has a third weld pad arranged therein, the fourth signal layer has a fourth weld pad arranged therein, the third weld pad and the fourth weld pad are coaxial with the second via and electrically connected to the conductive film coated on the inner sidewall of the second via, the PCB further has at least one second signal transmission line, each second transmission line comprises a third portion and the fourth portion, the third portion is arranged in the third signal layer corresponding to the third weld pad, the fourth portion is arranged in the fourth signal layer corresponding to the fourth weld pad, each of the first reference layer and the second reference layer defines a second through hole coaxial with the second via, the radius of the second via is R3, the radius of the second through hole is R4, R4=R3+d2, 1.5 mils≦d2≦4 mils.

15. The PCB of claim 14, wherein the value of d2 is approximately 3 mils or approximately 4 mils.
